(19) United States
(12) Patent Application Publication
(10) Pub. No.: US 2020/0321560 A1
(43) Pub. Date: Oct. 8, 2020

(54) ORGANIC LIGHT-EMITTING DEVICE AND DISPLAY DEVICE

(71) Applicant: Wuhan China Star Optoelectronics Semiconductor Display Technology Co., Ltd., Wuhan (CN)

(72) Inventor: Bo WANG, Wuhan (CN)

(73) Assignee: Wuhan China Star Optoelectronics Semiconductor Display Technology Co., Ltd., Wuhan (CN)

(21) Appl. No.: 16/476,552

(22) PCT Filed: Apr. 3, 2019
(86) PCT No.: PCT/CN2019/081165

§ 371 Date: Jul. 9, 2019

(30) Foreign Application Priority Data
Jan. 23, 2019 (CN) 201910064655.8

(51) Int. Cl. H01L 51/52; H01L 51/50; H01L 27/32

(52) U.S. Cl. CPC H01L 51/5281; H01L 51/5012; H01L 51/5056; H01L 51/5218; H01L 51/5234; H01L 51/5072; H01L 51/006; H01L 27/3244; H01L 27/3211; H01L 2251/558; H01L 2251/308; H01L 2251/301; H01L 2251/5315; H01L 51/5253

(57) ABSTRACT

An organic light-emitting device is provided, including: a first electrode; a hole transport layer; a light-emitting layer of at least one color; an electron transport layer; a second electrode, a side of the second electrode away from the first electrode being a light exit side; and a light-coupling layer of at least one color, the same layer disposed on the light exit side; wherein the at least one color of the light-coupling layer corresponds to the at least one color of the light-emitting layer. The organic light-emitting device and display device are by providing a light-coupling layer and setting the thickness of the light-coupling layer corresponding to the light-emitting layer of different color to be different. The longer the wavelength of the light emitted by the light-emitting layer is, the thicker the thickness of the light-coupling layer is, and the higher the light-emitting efficiency is.

### FIELD OF INVENTION

The present invention relates to the field of displays and the like, and more particularly to an organic light-emitting device and a display device.

### BACKGROUND OF INVENTION

Organic Light Emitting Display (OLED) refers to the phenomenon that luminescent materials are driven by electric field to cause luminescence through carrier injection and recombination. Because they have the technical advantages such as no backlight, high contrast, thin thickness, wide viewing angle and fast response peed, they have become one of the key directions for the development of the display industry.

Since the top-emitting organic light-emitting device has a large aperture ratio, most of the currently industrial display devices employ a top-emitting organic light-emitting device. In the top-emitting display device, the light coupling is of great significance for the improvement of the performance of the OLED.

In the current prior art, due to the material and cost of the light-coupling layer, the light-coupling layers corresponding to the light-emitting layers of different colors adopt a uniform thickness, and the light-emitting layers of different colors cannot simultaneously achieve optimal optical coupling. This fact affects the luminous efficiency of the display device.

### SUMMARY OF INVENTION

In order to solve the above technical problem, the present invention provides an organic light-emitting device that increases the light-emitting efficiency of an organic light-emitting device and a display device by providing a light-coupling layer on the light exit side and different thicknesses of light-coupling layers used for light of different colors.

A technical solution to solve the above problems is as follows. The present invention provides an organic light-emitting device, comprising: a first electrode; a hole transport layer, disposed on the first electrode; a light-emitting layer of at least one color, disposed on the hole transport layer; an electron transport layer, disposed on the light-emitting layer; a second electrode disposed on the electron transport layer, a side of the second electrode away from the first electrode being a light exit side; and a light-coupling layer of at least one color, disposed on the light exit side; wherein the at least one color of the light-coupling layer corresponds to the at least one color of the light-emitting layer; and the longer the wavelength of the light emitted by the light-emitting layer is, the thicker the thickness of the light-coupling layer is.

In an embodiment of the invention, the longer the wavelength of the light emitted by the light-emitting layer is, the thicker the thickness of the light-emitting layer is.

In an embodiment of the invention, the light-emitting layer is one of a red light-emitting layer, a green light-emitting layer, and a blue light-emitting layer, and the light-coupling layer is one of a red light-coupling layer, a green light-coupling layer, and a blue light-coupling layer.

In an embodiment of the invention, the organic light-emitting device comprises a red light-emitting layer, a green light-emitting layer, and a blue light-emitting layer; and the organic light-emitting device comprises a red light-coupling layer, a green light-coupling layer, and a blue light-coupling layer, disposed in the same layer, wherein the red light-coupling layer corresponds to the red light-emitting layer; the green light-coupling layer corresponds to the green light-emitting layer; and the blue light-coupling layer corresponds to the blue light-emitting layer.

In an embodiment of the invention, the thickness of the green light-coupling layer is greater than the thickness of the blue light-coupling layer and less than the thickness of the red light-coupling layer; the thickness of the light-emitting layer is 20-50 nm; the thickness of the red light-coupling layer is 70-140 nm; the thickness of the green light-coupling layer is 60-120 nm; and the thickness of the blue light-coupling layer is 50-100 nm.

In an embodiment of the invention, the refractive index of the light-coupling layer is between 1.7 and 2.5.

In an embodiment of the invention, the first electrode is a total-reflection anode; the first electrode is a laminated structure of an indium tin oxide layer, a silver layer and an indium tin oxide layer in sequence; the second electrode is a semi-reflective semi-transmissive cathode; and the material used for forming the second electrode includes at least one of barium, calcium, magnesium, and silver.

In an embodiment of the invention, the material used for the hole transport layer includes at least one of 4,4′,4″-tris[2-naphthylphenylamino]triphenylamine, N,N′-di(1-naphthyl)-N,N′-diphenyl-1,1′-biphenyl-4-4′-diamine, and 4,4′-cyclohexyl bis[N,N-bis(4-methylphenyl)aniline], the hole transport layer having a thickness of 40-150 nm; and the material used for the electron transport layer includes at least one of 1,3,5-tris(1-phenyl-1H-benzimidazol-2-yl)benzene, 4,7-diphenyl-1,10-phenanthroline, and 1,3,5-tris[(3-pyridyl)-3-phenyl]benzene, the electron transport layer having a thickness of 20 to 80 nm.

The invention also provides a display device, comprising: an array substrate; an organic light-emitting device, disposed on the array substrate; and a thin film encapsulation layer, disposed on the light-coupling layer of the organic light-emitting device.

In an embodiment of the invention, the thin film encapsulation layer includes organic layers and inorganic layers which are alternately disposed with each other; the material for forming the inorganic layers includes at least one of cerium oxide, cerium nitride, cerium oxynitride, cerium carbonitride, and aluminum oxide; and the material used for forming the organic layers is acrylic or epoxy.

Beneficial effects are as follows. The organic light-emitting device and display device of the present invention are by providing a light-coupling layer and setting the thickness of the light-coupling layer corresponding to the light-emitting layer of different color to be different. The longer the wavelength of the light emitted by the light-emitting layer is, the thicker the thickness of the light-coupling layer is, and the higher the light-emitting efficiency is. By changing the optical thickness of the light-coupling layer, different current efficiencies can be obtained, and the light-emitting efficiency of the organic light-emitting device can be significantly adjusted. At the same time, the use of the light-coupling layer having a higher refractive index can extend the life of the organic light-emitting device while increasing light-emitting efficiency.

### DESCRIPTION OF DRAWINGS

In order to more clearly illustrate the technical solutions in the embodiments of the present invention, the drawings used in the description of the embodiments will be briefly described below. It is obvious that the drawings in the following description are only some embodiments of the present invention. Other drawings can also be obtained from those skilled in the art based on these drawings without paying any creative effort.

The invention is further explained below in conjunction with the drawings and embodiments.

FIG. 1 is a schematic structural view of an organic light-emitting device according to an embodiment of the present invention;

FIG. 2 is a graph showing the thickness and luminous efficiency of a red light-coupling layer according to an embodiment of the present invention;

FIG. 3 is a graph showing the thickness and luminous efficiency of a green light-coupling layer according to an embodiment of the present invention;

FIG. 4 is a graph showing the thickness and luminous efficiency of a blue light-coupling layer according to an embodiment of the present invention; and

FIG. 5 is a schematic structural view of a display device according to an embodiment of the present invention.

### Reference Mark

1 display device; 10 organic light-emitting device;
20 array substrate; 30 thin film encapsulation layer;
11 first electrode; 12 hole transport layer;
13 luminescent layer; 14 electron transport layer;
15 second electrode; 16 light-coupling layer;
131 red light-emitting layer; 132 green light-emitting layer;
133 blue light-emitting layer; 161 red light-coupling layer;
162 green light-coupling layer; 163 blue light-coupling layer;
100 light exit side.

### DETAILED DESCRIPTION OF PREFERRED EMBODIMENTS

The embodiments of the present invention are described in detail below, and the examples of the embodiments are illustrated in the drawings, wherein the same or similar reference numerals indicate the same or similar elements or elements having the same or similar functions. The embodiments described below with reference to the drawings are intended to be illustrative of the invention and are not to be construed as limiting.

The following description of the embodiments is with reference to the drawings and is provided to illustrate the specific embodiments of the invention. The directional terms mentioned in the present invention, such as ‘upper’, ‘lower’, ‘front’, ‘back’, ‘left’, ‘right’, ‘top’, ‘bottom’, etc., are only the directions in the drawings. Therefore, the directional terminology used is for the purpose of illustration and understanding of the invention rather than limiting the invention.

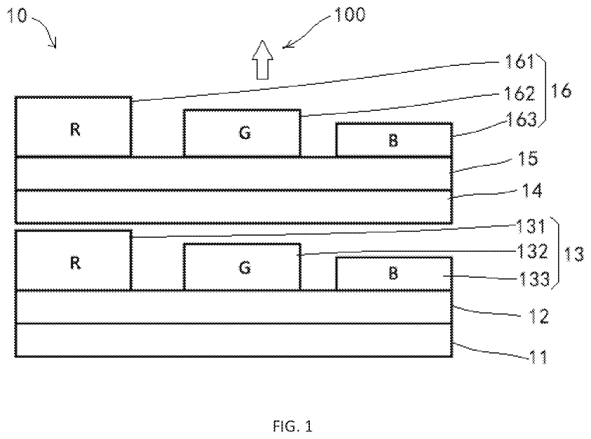

As shown in FIG. 1, in an embodiment, an organic light-emitting device 10 of the present invention includes a first electrode 11, a hole transport layer 12, a light-emitting layer 13 of at least one color, an electron transport layer 14, a second electrode 15, and an light-coupling layer 16 of at least one color.

The organic light-emitting device 10 is a top-emitting organic light-emitting device 10, and therefore, the first electrode 11 in this embodiment is a total-reflection anode. The specific structure thereof is a laminated structure of an indium tin oxide layer, a silver layer and an indium tin oxide layer in sequence. The second electrode 15 is a semi-reflective semi-transmissive cathode; and the material used for forming the second electrode 15 includes at least one of barium, calcium, magnesium, and silver. Therefore, the side of the second electrode 15 away from the first electrode 11 is the light exit side 100.

The hole transport layer 12 is disposed on the first electrode 11. In this embodiment, the material used for the hole transport layer 12 includes at least one of 4,4′,4″-tris[2-naphthylphenylamino]triphenylamine, N,N′-di(1-naphthyl)-N,N′-diphenyl-1,1′-biphenyl-4-4′-diamine, and 4,4′-cyclohexyl bis[N,N-bis(4-methylphenyl)aniline]. In a specific preparation, the present embodiment deposits at least one of 4,4′,4″-tris[2-naphthylphenylamino]triphenylamine, N,N′-di(1-naphthyl)-N,N′-diphenyl-1,1′-biphenyl-4-4′-diamine, and 4,4′-cyclohexyl bis[N,N-bis(4-methylphenyl)aniline] on the first electrode 11 by a vacuum thermal evaporation process to form the hole transport layer 12 having a thickness of 40-150 nm.

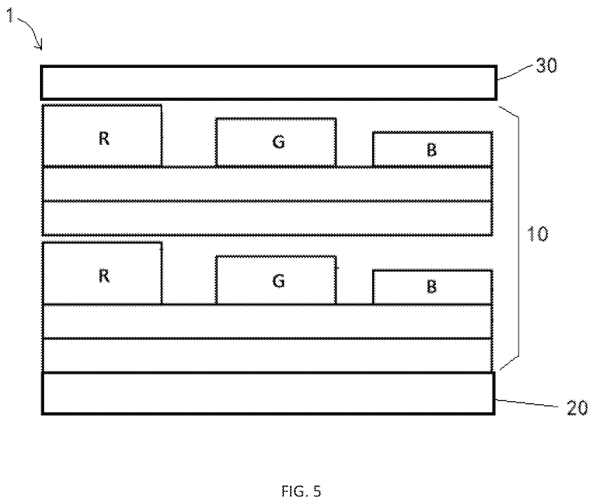

A light-emitting layer 13 of at least one color is provided on the hole transport layer 12. The light-emitting layer 13 is one of a red light-emitting layer 131, a green light-emitting layer 132, and a blue light-emitting layer 133. In the present embodiment, the organic light-emitting device 10 includes a red light-emitting layer 131, a green light-emitting layer 132, and a blue light-emitting layer 133; and the red light-emitting layer 131, the green light-emitting layer 132, and the blue light-emitting layer 133 are set on the same layer. The thickness of the luminescent layer 13 is 20-50 nm; the thickness of the red luminescent layer 131 is greater than the thickness of the green luminescent layer 132; and the thickness of the green luminescent layer 132 is greater than the thickness of the blue luminescent layer 133. In this embodiment, the thickness of the red light-emitting layer 131 is preferably 40 nm to 50 nm, the thickness of the green light-emitting layer 132 is preferably 30 nm to 40 nm, and the thickness of the blue light-emitting layer 133 is preferably 20 nm to 30 nm. In the actual preparation process, the luminescent material is deposited in the pixel-delimiting layer of the array substrate 20 (referring to FIG. 5) through a metal mask plate.

The electron transport layer 14 is disposed on the light-emitting layer 13; and the second electrode 15 is disposed on the electron transport layer 14. In this embodiment, the material used for the electron transport layer 14 includes at least one of 1,3,5-tris(1-phenyl-1H-benzimidazol-2-yl)benzene, 4,7-diphenyl-1,10-phenanthroline, and 1,3,5-tris[(3-pyridyl)-3-phenyl]benzene. In the actual preparation process, at least one of 1,3,5-tris(1-phenyl-1H-benzimidazol-2-yl)benzene, 4,7-diphenyl-1,10-phenanthroline, and 1,3,5-tris[(3-pyridyl)-3-phenyl]benzene is deposited on the light-emitting layer 13 by a vacuum thermal evaporation process to form the electron transport layer 14. The electron transport layer 14 has a thickness of 20 to 80 nm.

A light-coupling layer 16 of at least one color is disposed on the light exit side 100, specifically disposed on the electron transport layer 14. The light-coupling layer 16 is one of a red light-coupling layer 161, a green light-coupling layer 162, and a blue light-coupling layer 163. In the present embodiment, the organic light-emitting device 10 includes a red light-coupling layer 161, a green light-coupling layer 162, and a blue light-coupling layer 163; and the red light-coupling layer 161, the green light-coupling layer 162, and the blue light-coupling layer 163 are disposed on the same layer and disposed on the light exit side 100; wherein each of the light-coupling layers 16 corresponds to a light-emitting layer 13 of the same color, that is, the red light-coupling layer 161 corresponds to the red light-emitting layer 131, the green light-coupling layer 162 corresponds to the green light-emitting layer 132, and the blue light-coupling layer 163 corresponds to the blue light emitting layer 133.

In order to increase the light-emitting effect of the organic light-emitting device 10, the longer the wavelength of the light emitted from the light-emitting layer 13 is, the thicker the thickness of the light-coupling layer 16 is. Further, the longer the wavelength of the light emitted from the light-emitting layer 13 is, the thicker the thickness of the light-emitting layer 13 is.

In this embodiment, since the light-emitting layer 13 is a red light-emitting layer 131, a green light-emitting layer 132, and a blue light-emitting layer 133, and in the three-color light-emitting layer 13, the wavelength of the red light emitted by the red light-emitting layer 131 is the longest and the wavelength of the blue light emitted by the blue light-emitting layer 133 is the shortest, therefore, the thickness of the green light-coupling layer 162 is greater than the thickness of the blue light-coupling layer 163 and is smaller than that of the red light-coupling layer 161.

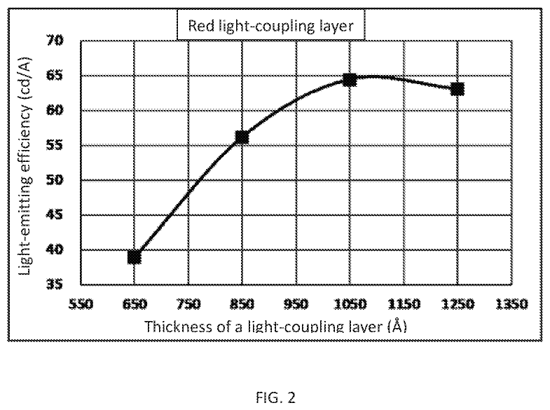

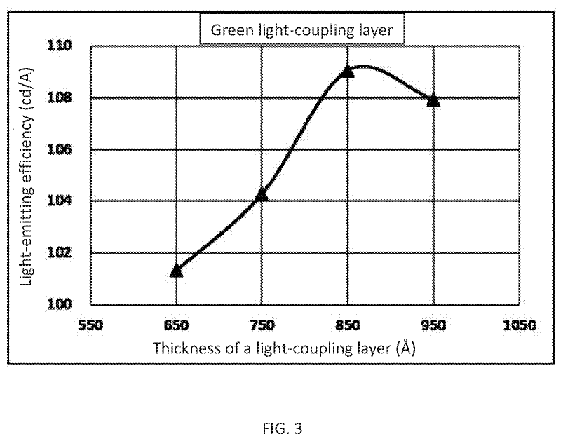

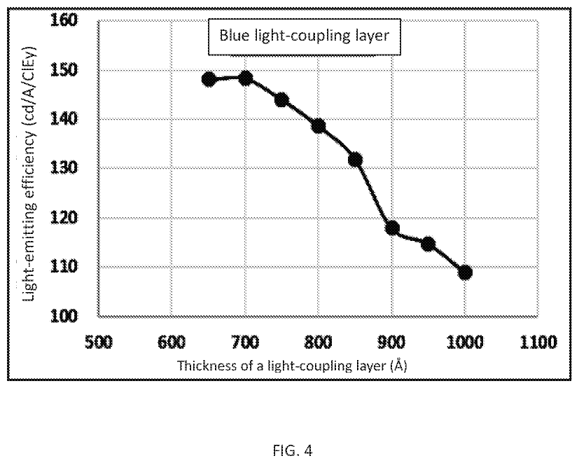

In order to simultaneously consider the thickness of the organic light-emitting layer 13 and the light-emitting efficiency, the thickness of the red light-coupling layer 161 in the embodiment is 70-140 nm, preferably 105 nm, that is, when the thickness of the red light-coupling layer 161 is 105 nm, the organic light-emitting device has the highest luminous efficiency, as shown in FIG. 2; the thickness of the green light-coupling layer 162 is 60-120 nm, preferably 85 nm, that is, when the thickness of the green light-coupling layer 162 is 85 nm, the organic light-emitting device has the highest luminous efficiency, as shown in FIG. 3; and the thickness of the blue light-coupling layer 163 is 50-100 nm, preferably 70 nm, that is, when the thickness of the blue light-coupling layer 163 is 70 nm, the organic light-emitting device has the highest luminous efficiency, as shown in FIG. 4.

Referring to FIG. 2 to FIG. 4, since the wavelengths of the lights of different colors are different, the thickness of the light-coupling layer 16 corresponding to the light-emitting layer 13 of different color is also different. The longer the wavelength of the light emitted by the light-emitting layer 13 is, the thicker the thickness of the light-coupling layer 16 is, and the higher the light-emitting efficiency is. In the present embodiment, by changing the optical thickness of the light-coupling layer 16, different current efficiencies can be obtained, and the light-emitting efficiency of the organic light-emitting device 10 can be significantly adjusted.

In addition, the refractive index of the light-coupling layer 16 is also a factor affecting the light-emitting efficiency. In the embodiment, the refractive index of the light-coupling layer 16 is between 1.7 and 2.5. The light-coupling layer 16 having a higher refractive index can extend the life of the organic light-emitting device 10 while increasing light-emitting efficiency.

As shown in FIG. 5, the embodiment further provides a display device 1 including an array substrate 20, an organic light-emitting device 10, and a thin film encapsulation layer 30.

The organic light-emitting device 10 is disposed on the array substrate 20. The first electrode 11 of the organic light-emitting device 10 is disposed in the array substrate 20, the pixel-delimiting layer in the array substrate 20 is provided with an opening, and the first electrode 11 is exposed in the opening. The light-emitting layer 13 is disposed in these openings.

The thin film encapsulation layer 30 is disposed on the light-coupling layer 16 of the organic light-emitting device 10. The thin film encapsulation layer 30 includes organic layers and inorganic layers which are alternately disposed with each other. The material for forming the inorganic layers includes at least one of cerium oxide, cerium nitride, cerium oxynitride, cerium carbonitride, and aluminum oxide. The material used for forming the organic layers is acrylic or epoxy.

The main design point of the display device 1 of the present embodiment is the organic light-emitting device 10. For other devices or structures, such as the array substrate 20, the color filter substrate, and the like, the description will not be repeated.

The above are only the preferred embodiments of the present invention, and are not intended to limit the present invention. Any modifications, equivalents, and improvements made within the spirit and scope of the present invention should be included inside the scope of the present invention.

What is claimed is:

1. An organic light-emitting device, comprising:
a first electrode;
a hole transport layer, disposed on the first electrode;
a light-emitting layer of at least one color, disposed on the hole transport layer;
an electron transport layer, disposed on the light-emitting layer;
a second electrode disposed on the electron transport layer, a side of the second electrode away from the first electrode being a light exit side; and
a light-coupling layer of at least one color, disposed on the light exit side;
wherein the at least one color of the light-coupling layer corresponds to the at least one color of the light-emitting layer; and
the longer the wavelength of the light emitted by the light-emitting layer is, the thicker the thickness of the light-coupling layer is.

2. The organic light-emitting device as claimed in claim 1, wherein, the longer the wavelength of the light emitted by the light-emitting layer is, the thicker the thickness of the light-emitting layer is.

3. The organic light-emitting device as claimed in claim 1, wherein the light-emitting layer is one of a red light-emitting layer, a green light-emitting layer, and a blue light-emitting layer, and the light-coupling layer is one of a red light-coupling layer, a green light-coupling layer, and a blue light-coupling layer.

4. The organic light-emitting device as claimed in claim 3, wherein the organic light-emitting device comprises a red light-emitting layer, a green light-emitting layer, and a blue light-emitting layer, disposed in the same layer; and the organic light-emitting device comprises a red light-coupling layer, a green light-coupling layer, and a blue light-coupling layer, disposed in the same layer, wherein the red light-coupling layer corresponds to the red light-emitting layer; the green light-coupling layer corresponds to the green light-emitting layer; and the blue light-coupling layer corresponds to the blue light-emitting layer.

5. The organic light-emitting device as claimed in claim 4, wherein the thickness of the green light-coupling layer is greater than the thickness of the blue light-coupling layer and less than the thickness of the red light-coupling layer; the thickness of the light-emitting layer is 20-50 nm; the thickness of the red light-coupling layer is 70-140 nm; the thickness of the green light-coupling layer is 60-120 nm; and the thickness of the blue light-coupling layer is 50-100 nm.

6. The organic light-emitting device as claimed in claim 1, wherein the refractive index of the light-coupling layer is between 1.7 and 2.5.

7. The organic light-emitting device as claimed in claim 5, wherein
the first electrode is a total-reflection anode; the first electrode is a laminated structure of an indium tin oxide layer, a silver layer and an indium tin oxide layer in sequence;
the second electrode is a semi-reflective semi-transmissive cathode; and the material used for forming the second electrode includes at least one of barium, calcium, magnesium, and silver.

8. The organic light-emitting device as claimed in claim 1, wherein the material used for the hole transport layer includes at least one of 4,4′,4″-tris[2-naphthylphenylamino]triphenylamine, N,N′-di(1-naphthyl)-N,N′-diphenyl-1,1′-biphenyl-4-4′-diamine, and 4,4′-cyclohexyl bis[N,N-bis(4-methylphenyl)aniline], the hole transport layer having a thickness of 40-150 nm; and
the material used for the electron transport layer includes at least one of 1,3,5-tris(1-phenyl-1H-benzimidazol-2-yl)benzene, 4,7-diphenyl-1,10-phenanthroline, and 1,3,5-tris[(3-pyridyl)-3-phenyl]benzene, the electron transport layer having a thickness of 20 to 80 nm.

9. A display device, comprising:
an array substrate;
the organic light-emitting device as claimed in claim 1, disposed on the array substrate; and
a thin film encapsulation layer, disposed on the light-coupling layer of the organic light-emitting device.

10. The display device as claimed in claim 9, wherein the thin film encapsulation layer includes organic layers and inorganic layers which are alternately disposed with each other;
the material for forming the inorganic layers includes at least one of cerium oxide, cerium nitride, cerium oxynitride, cerium carbonitride, and aluminum oxide; and
the material used for forming the organic layers is acrylic or epoxy.
